(19) United States
(12) Patent Application Publication
(10) Pub. No.: US 2005/0207242 A1
(43) Pub. Date: Sep. 22, 2005

(54) Semiconductor memory device with a hierarchical bit lines, having row redundancy means

(76) Inventor: Tomoaki Yabe, Kawasaki-shi (JP)

Correspondence Address: OBLON, SPIVAK, MCCLELLAND, MAIER & NEUSTADT, P.C., 1940 DUKE STREET, ALEXANDRIA, VA, 22314, US

(21) Appl. No.: 10/959,210

(22) Filed: Oct. 7, 2004

(30) Foreign Application Priority Data
Mar. 16, 2004 (JP) 2004-074967

(51) Int. Cl. G11C 7/00

(52) U.S. Cl. 365/200

(57) ABSTRACT

A semiconductor memory device is provided which includes sub-arrays and a spare sub-array, in which memory cells are arranged in row and columns. The spare sub-array replaces a sub-array including a faulty memory cell. First local bit lines are connected to the memory cells of each sub-array. A second local bit line is connected to the memory cells of the spare sub-array. A global bit line is shared by the first local bit lines and the second local bit line. Transfer gates set connections of each of the local bit lines to the global bit line. Sub-array decoders are provided in correspondence with the respective sub-arrays, and select the sub-arrays. A switch circuit changes correlation between the sub-arrays and the spare sub-array and the sub-array decoders. A fuse element, in which the correlation in the switch circuit is stored, outputs a signal indicating the correlation to the switch circuit.

### CROSS-REFERENCE TO RELATED APPLICATIONS

This application is based upon and claims the benefit of priority from prior Japanese Patent Application No. 2004-074967, filed Mar. 16, 2004, the entire contents of which are incorporated herein by reference.

### BACKGROUND OF THE INVENTION

1. Field of the Invention

This invention relates to a semiconductor memory device with a hierarchical bit lines, having row redundancy means which relieves faulty memory cells by replacing them with non-faulty cells.

2. Description of the Related Art

Recently, with increase in the packing density of memory cells, semiconductor memory devices having hierarchical bit lines have been receiving attention. The following is explanation of an SRAM (static random access memory) having hierarchical bit lines, as an example of a conventional semiconductor memory device having hierarchical bit lines, and problems thereof.

FIG. 1 is a schematic diagram illustrating a structure of a conventional SRM having hierarchical bit lines. A cell array 101 is divided into 64 sub-arrays <0>-<63>, and bit line buffers 102 are arranged between respective adjacent sub-arrays. Further, row decoders 103, a column decoder and input/output (I/O) circuit 104, and a fuse element 105 are arranged in the vicinity of the cell array 101.

FIG. 2 is a circuit diagram of the sub-arrays and the row decoders in the SRAM. Although each sub-array has plural pairs of bit lines, FIG. 2 illustrates only one pair of local bit lines BL0-0 and BL0-0B in the sub-array <0>. In the sub-array <0>, 16 memory cells M0-M15 and one spare memory cell MS are connected to the local bit lines BL0-0 and BL0-0B. The local bit lines BL0-0 and BL0-0B are connected to global bit lines GBL and GBLB via write transfer gates NM1 and NM2, respectively. The global bit lines GBL and GBLB are connected to all the sub-arrays <0>-<63>. The input/output (I/O) circuit 104 performs reading from and writing into the sub-arrays <0>-<63) via the global bit lines GBL and GBLB.

Further, one of a pair of local bit lines, for example, the local bit line BL0-0, is configured to drive the global bit line GBL via a reading NAND buffer ND1 and a global bit line reading driver NM3. A source of the global bit line reading driver NM3 is connected to a drain of a column switch NM4. A gate of the column switch NM4 is connected to a column selection line CSL which is driven by the column decoder 104.

The SRAM structured as described above adopts a single-bit-line reading method, in which data stored in memory cells is read out by using one of the pair local bit lines BL0-0 and BL0-0B and one of the pair global bit lines GBL and GBLB. This is because a high-speed operation is difficult in a method of connecting a differential amplification sense amplifier to a bit line pair, since variations in property of transistors have become large with scale down thereof (for example, refer to K. Zhang et al., “The Scaling of Data Sensing Schemes for High Speed Cache Design in Sub-0.18 μm Technologies”, Tech. Dig. of VLSI Circuits Symp.2000, June 2000, pp. 226-227).

In FIG. 2, a spare word line SWL connected to the spare memory cell MS and word lines WL0-WL15 connected to the 16 memory cells M0-M15, respectively, are driven by the row decoder 103 of the sub-array they belong. It is designated by lower 4 bits (RA0-RA3) of a row addresses RA0-RA9 formed of data of 10 bits, which memory cell is selected from the 16 memory cells. Further, RA4-RA9 designate the sub-array to be selected.

The spare word line SWL is driven by a spare word line driver DS. As a drive signal for the spare word line SWL, the spare word line driver DS outputs an AND of a sub-array selection signal BS0 and an output of a two-state selection switch SRS. The sub-array selection signal BS0 is obtained by decoding the row addresses RA4-RA9. The two-state selection switch SRS selects and outputs one of a ground potential VSS and a decode signal PS0 of the row addresses RA0-RA3 corresponding to the word line WL0.

A driver D0 which drives the word line WL0 outputs an AND of the sub-array selection signal BS0 and a three-state selection switch RS0 to the word line WL0. The three-state selection switch RS0 selects and outputs one of the ground potential V_{SS}, the decode signal PS0, and a decode signal PS1 of the row addresses RA0-RA3 corresponding to the word line WL1.

When each of the other word lines WL1-WL15 is driven, in the same manner as the word line WL0, an AND of the sub-array selection signal BS0 and its three-state selection switch (RS1-RS15) is outputted to the word line (WL1-WL15). Each of the three-state selection switches RS0-RS15 selects and outputs one of the ground potential V_{SS}, a decode signal corresponding to its word line, and a decode signal corresponding to the following word line. In this step, program as to which signals are to be selected by the two-state selection switch SRS and the three-state selection switches RS0-RS15 of the word lines is stored in the fuse element 105. Any word line among the word lines WL0-WL15, which is connected to a faulty memory cell, can be relieved by the spare word line SWL by properly programming the fuse element. The following is an explanation of a relieving method.

The states of the selection switches SRS and RS0-RS15 shown in FIG. 2 correspond to the case where there are no word lines connected to a faulty memory cell and fault relief by the spare word line SWL is not performed. Specifically, the two-state selection switch SRS selects the ground potential V_{SS}, and the spare word line SWL is set to “Low” (hereinafter referred to as “L”) and inactivated. The three-state selection switches RS0-RS15 select the decoded signals PS0-PS15, respectively. Thereby, the word lines WL0-WL15 are activated in response to the decoded signals PS0-PS15, respectively.

Next, FIG. 3 shows a method of relieving fault in the case where the word line WL0 is connected to a faulty memory cell. In this case, it is programmed such that the two-state selection switch SRS selects the decode signal PS0 and the three-state selection switch RS0 selects the ground potential V_{SS}. The other three-state selection switches RS1-RS15 are programmed to select the decode signals PS1-PS15, respectively, in the same manner as shown in FIG. 2. In this case, the word line WL0 is set to “L”, and access thereto is stopped. Instead of it, the spare word line SWL, which is activated or inactivated by the decode signal PS0 corresponding to the word line WL0, performs the same operation as that of the original word line WL0. Thereby, the word line WL0 connected to a faulty memory cell is replaced by the spare word line SWL. Specifically, the spare word line SWL relieves the faulty word line WL0.

Generally, if a memory cell connected to a word line WLₙ is faulty, a three-state selection switch RSₙ is programmed to select the ground potential V_{SS}, a two-state selection switch SRS is programmed to select the decode signal PS0, each three-state selection switch Rsi(i=0, 1, . . . n−1) select a decode signal Psi+1, and each three-state selection switch RSj(j=n+1, n+2, . . . , 15) select a decode signal PSj. Thereby, the correlations between the word line drivers of the word lines WL0-WLn and the address decode signals shift such that the word line drivers select respective one-shifted address decode signals. Thereby the word line WLn is relieved by the spare word line SWL. This method is called a shift word line redundancy method.

However, in the conventional shift word line redundancy methods, it is necessary to provide a spare word line for each sub-array. Therefore, they have a problem that the area of each sub-array increases, and it is impossible to reduce the area of a memory cell array portion constituted by a plurality of sub-arrays. In other words, they have a problem that they bear a large area penalty of providing a spare word line for each sub-array. In particular, if the number of word lines in a sub-array is small, they have a large area penalty. For example, in the above example, it is necessary to provide one spare word line for 16 word lines in a sub-array, and thus the area penalty in the memory cell array portion reaches about 6%.

### BRIEF SUMMARY OF THE INVENTION

A semiconductor memory device according to one aspect of the present invention comprises: a plurality of sub-arrays, in each of which memory cells are arranged in row and columns; a spare sub-array which replaces a sub-array including a faulty memory cell in the plurality of sub-arrays, the spare sub-array including memory cells arranged in rows and columns; a plurality of first local bit lines connected to the memory cells of the respective sub-arrays; a second local bit line connected to the memory cells of the spare sub-array; a global bit line shared by the plurality of first local bit lines and the second local bit line; a plurality of transfer gates which set connections of each of the plurality of the first bit lines and the second local bit line to the global bit line to a connected state or a disconnected state; a plurality of sub-array decoders which select the sub-arrays, the sub-array decoders being provided in correspondence with the respective sub-arrays; a switch circuit which changes correlation between the sub-arrays and the spare sub-array and the sub-array decoders; and a fuse element, in which the correlation in the switch circuit is stored, the fuse element outputting a signal indicating the correlation to the switch circuit.

### BRIEF DESCRIPTION OF THE SEVERAL VIEWS OF THE DRAWING

FIG. 1 is a schematic diagram illustrating a structure of a conventional semiconductor memory device having hierarchical bit lines.

FIG. 2 is a circuit diagram illustrating structures of sub-arrays and row decoders in the conventional semiconductor memory device.

FIG. 3 is a circuit diagram illustrating a method of relieving fault of a word line WL0 connected to a faulty memory cell in the conventional semiconductor memory device.

FIG. 4 is a schematic diagram illustrating a structure of a semiconductor memory device according to an embodiment of the present invention.

FIG. 5 is a circuit diagram illustrating structures of sub-arrays, a spare sub-array, and row decoders in the semiconductor memory device of the embodiment.

FIG. 6 is a schematic diagram illustrating a case of not performing fault relief of a sub-array in the semiconductor memory device of the embodiment.

FIG. 7 is a schematic diagram illustrating a method of relieving a sub-array <0> in the semiconductor memory device of the embodiment.

FIG. 8 is a schematic diagram illustrating a method of relieving a sub-array <1> in the semiconductor memory device of the embodiment.

FIG. 9 is a circuit diagram illustrating a structure of a three-state selection switch in the semiconductor memory device of the embodiment.

FIG. 10 is a circuit diagram illustrating a structure of a two-state selection switch SSS in the semiconductor memory device of the embodiment.

FIG. 11 is a circuit diagram illustrating a structure of a two-state selection switch SS63 in the semiconductor memory device of the embodiment.

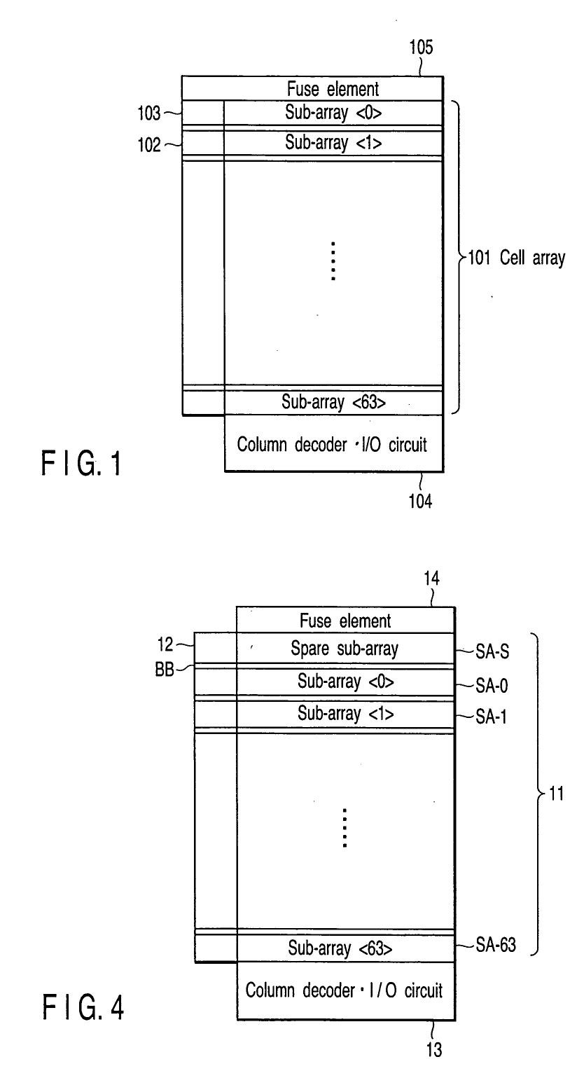

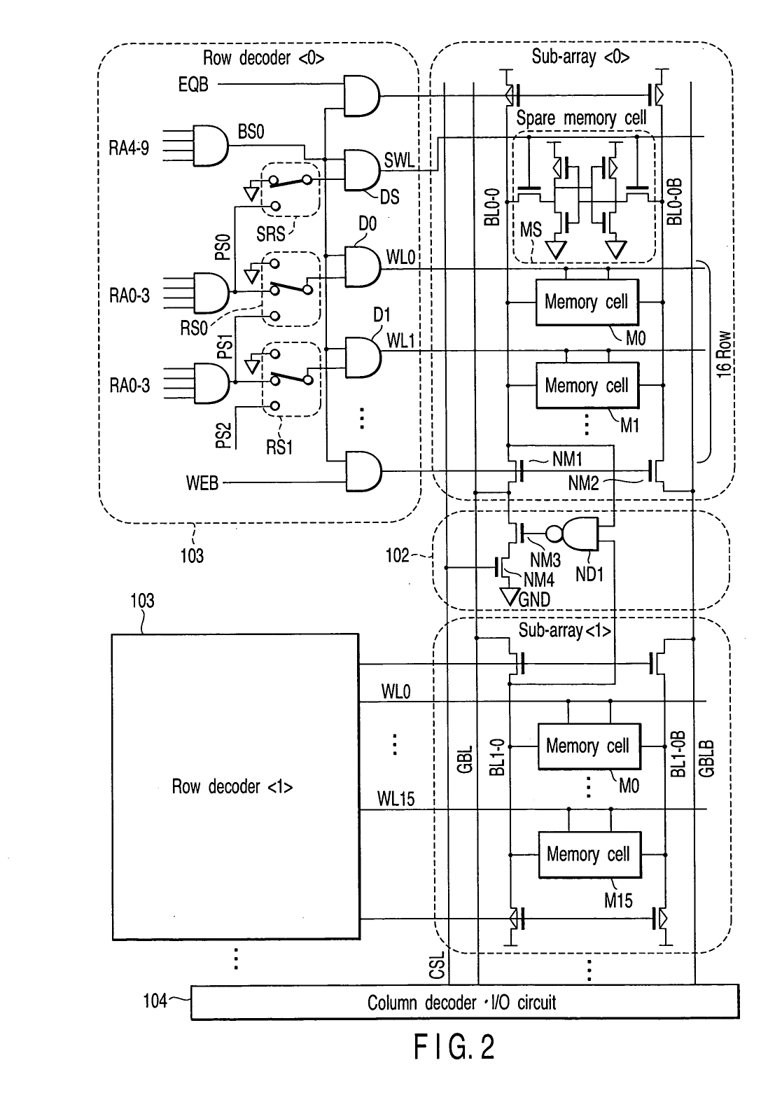

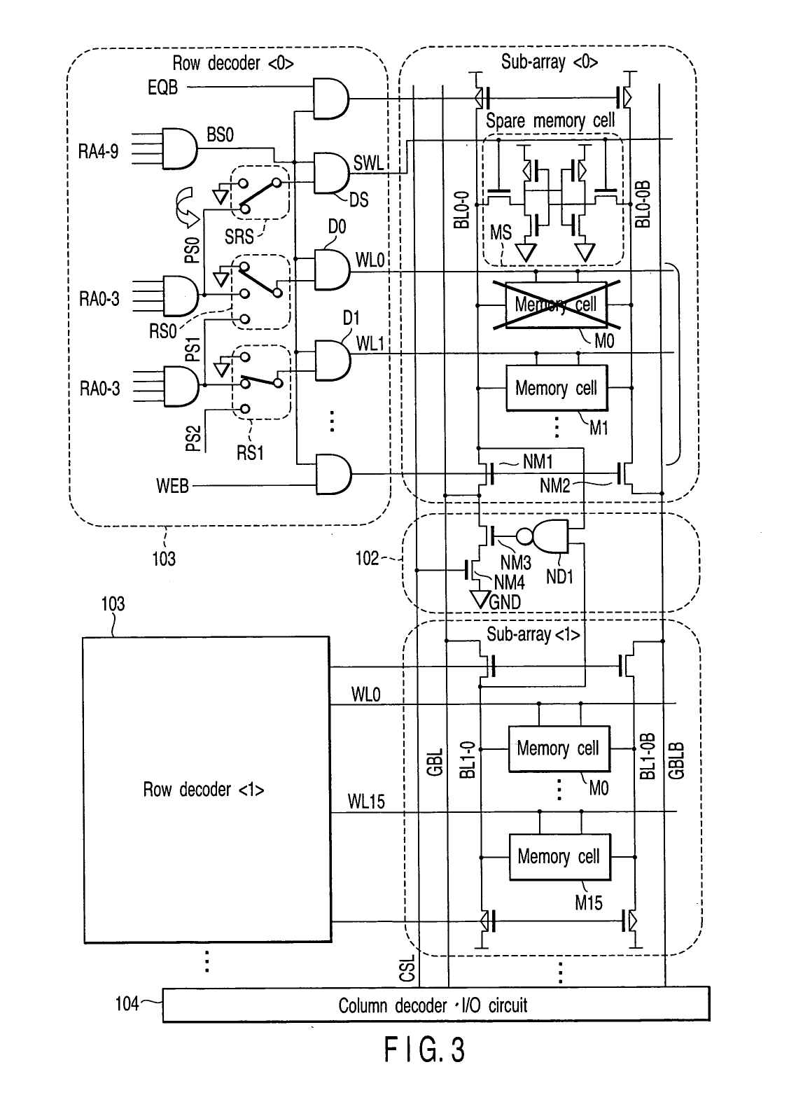

### DETAILED DESCRIPTION OF THE INVENTION

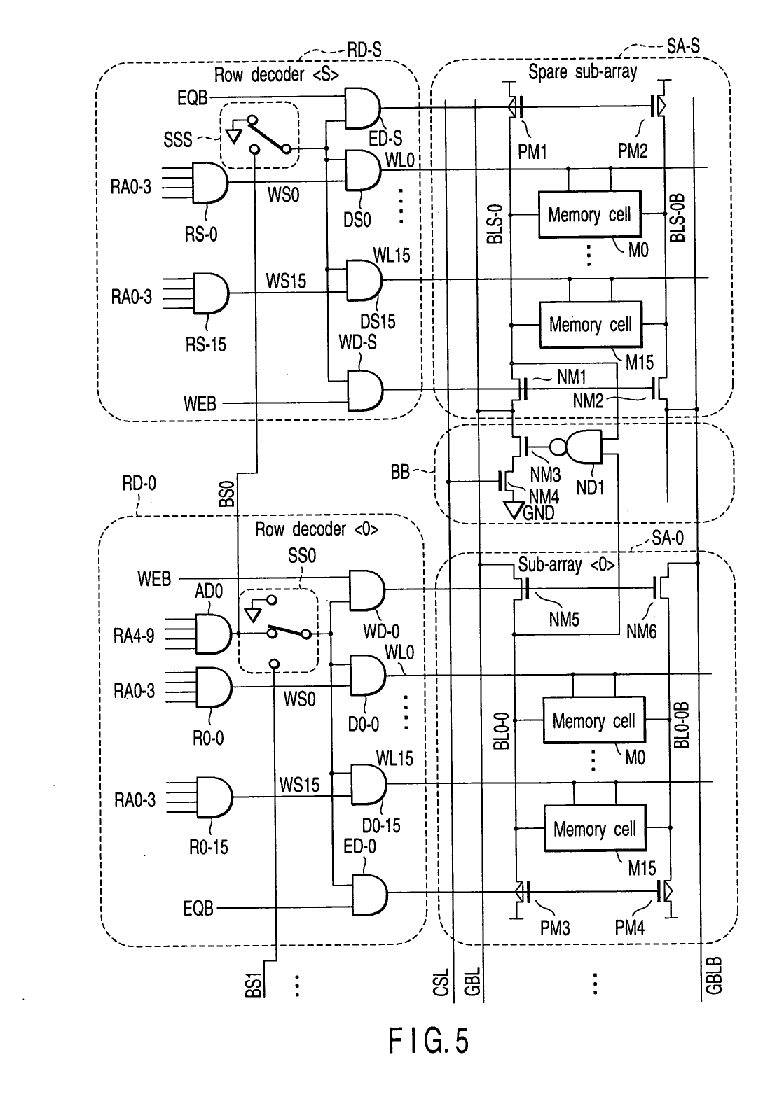

A semiconductor memory device according to an embodiment of the present invention is explained below with reference to FIGS. 4 to 11. An SRAM is used as an example of the semiconductor memory device. In the explanation, like reference numerals are assigned to like constituent elements through the drawings.

FIG. 4 is a schematic diagram illustrating a structure of an SRAM according to an embodiment of the present invention. The SRAM comprises a cell array 11, row decoders 12, a column decoder and input/output (I/O) circuit 13, and a fuse element 14. In this embodiment, the SRPAM has a storage capacity of 512 k bits, and the cell array 11 has memory cells of 1024 rows and 512 columns. The cell array 11 is formed of 64 sub-arrays constituted by sub-array <0> SA-0 to sub-array <63> SA-63, one spare sub-array SA-S, and bit line buffers BB. Each of the sub-arrays <0>-<63> and the spare sub-array SA-S has memory cells of 16 rows and 512 columns. The spare sub-array SA-S is used in place of a sub-array having a faulty memory cell, and relieves the sub-array including the faulty memory cell. The bit line buffers BB are arranged between the spare sub-array SA-A and the sub-array <0> and between the adjacent sub-arrays.

FIG. 5 is a circuit diagram illustrating structures of the sub-arrays, the spare sub-array, and the row decoders in the SRAM of the embodiment. FIG. 5 shows the spare sub-array SA-S, the sub-array <0> SA-0, a row decoder RD-S which selects word lines of the spare sub-array SA-S, a row decoder RD-0 which selects word lines of the sub-array <0> SA-0, and the bit line buffer BB.

Although the spare sub-array SA-S has 512 pairs of local bit lines, FIG. 5 only shows a pair of local bit lines BLS-0 and BLS-0B. The local bit lines BLS-0 and-BLS-0B are connected with 16 memory cells M0-M15. The memory cells M0-M15 are connected with word lines WL0-WL15, respectively. The local bit lines BLS-0 and BLS-0B are connected to global bit lines GBL and GBLB via write transfer gates NM1 and NM2, respectively. Each of the write transfer gates NM1 and NM2 is formed of an n-channel MOS field-effect transistor. The input/output (I/O) circuit 14 performs reading from and writing into the spare sub-array SA-S via the global bit lines GBL and GBLB.

One of the pair of local bit lines, for example, the local bit line BLS-0, drives the global bit line GBL via a reading NAND buffer ND1 and a global bit line reading driver NM3. The global bit line reading driver NM3 is supplied with a ground potential GND via a column switch NM4. Each of the reading driver NM3 and the column switch NM4 is formed of an n-channel MOS field-effect transistor. More specifically, the local bit line BLS-0 is connected to a first input terminal of the reading NAND buffer ND1, and an output terminal of the reading NAND buffer ND1 is connected to a gate of the global bit line reading driver NM3. A drain of the reading driver NM3 is connected to the global bit line GBL, and a source of the reading driver NM3 is connected to a drain of the column switch NM4. A source of the column switch NM4 is supplied with the ground potential. Further, a gate of the column switch NM4 is connected to a column selection line CSL which is driven by the column decoder 13.

Although the sub-array <0> SA-0 also has 512 pairs of local bit lines, FIG. 5 only shows a pair of local bit lines BL0-0 and BL0-0B. The local bit lines BL0-0 and BL0-0B are connected with 16 memory cells M0-M15. The memory cells M0-M15 are connected with word lines WL0-WL15, respectively. The local bit lines BL0-0 and BL0-0B are connected to the global bit lines GBL and GBLB via write transfer gates NM5 and NM6, respectively. Each of the write transfer gates NM5 and NM6 is formed of an n-channel MOS field-effect transistor. The global bit lines GBL and GBLB are connected to all the sub-arrays <0>-<63>. The input/output (I/O) circuit 14 performs reading from and writing into the sub-arrays <0>-<63> via the global bit lines GBL and GBLB.

One of the pair of local bit lines, for example, the local bit line BL0-0, is connected to the first input terminal of the reading NAND buffer ND1, and drives the global bit line GBL via the reading NAND buffer ND1 and the global bit line reading driver NM3.

In the SRAM structured as described above, reading is performed via one bit line, and writing is performed by using both bit lines being a pair, as follows.

In reading, when a column is selected (when the column selection line CSL is in the state “High” (referred to as “H” hereinafter)) and the local bit line BL0-0 is set to the state “L” (Low) by a memory cell, that is, if data “0” is stored in the memory cell, the reading driver NM3 is turned on via the reading NAND buffer ND1. Thereby, the global bit line GBL is driven to the state “L”, and the data “0” is read by the input/output (I/O) circuit 13. Further, if the local bit line BL0-0 maintains the state “H” in the column, that is, if data “1” is stored in the memory cell, the reading driver NM3 is turned off. Thereby, the global bit line GBL maintains the state “H”, and the data “1” is read by the input/output (I/O) circuit 13.

As described above, this example adopts a single-bit-line reading method in which data stored in a memory cell is read out by using only one of the pair of local bit lines BL0-0 and BL0-0B and one of the pair of global bit lines GBL and GBLB. In this method, even if variations in property of transistors increase with scale down thereof, high-speed operation is easily performed in comparison with the method of connecting a differential amplifying sense amplifier to a bit line pair.

In this single-bit-line reading method, the level of a bit line is sensed by the reading NAND buffer ND1, and thus it is necessary to greatly change the voltage of the local bit line BL0-0 in its variable range (from maximum to minimum value, and vice versa) at high speed. Therefore, the number of memory cells connected to the local bit lines BL0-0 and BL0-0B is limited to 16, and thereby the capacity of the local bit lines is minimized.

In the meantime, in writing, both the pair local bit lines BL0-0 and BL0-0B and the both the pair global bit lines GBL and GBLB are used. In writing, desired data is written into a memory cell by driving the pair of local bit lines BL0-0 and BL0-0B from the global bit lines GBL and GBLB via the writing transfer gates NM5 and NM6. The above hierarchical bit line type SRAM is very effective in the field of SRAMs required to operate at high speed with scale down of SRAMs hereafter.

The following is explanation of operations of the row decoders, the spare sub-array, and the sub-arrays.

The word lines WL0-WL15 connected to the memory cells in the spare sub-array SA-S are driven by the row decoder RD-S. Further, the word lines WL0-WL15 connected to the memory cells in the sub-array SA-0 are driven by the row decoder RD-0. It is designated by lower 4 bits (RA0-RA3) of a row addresses RA0-RA9 formed of data of 10 bits which memory cell is selected from the 16 memory cells M0-M15. Further, it is designated by row addresses RA4-RA9 which sub-array is selected.

In the spare sub-array SA-S, as shown in FIG. 5, each of the word line drivers DS-0 to DS-15 outputs an AND of a selection signal (WSO-WS15) of its word line (WL0-WL15) and an output of the two-state selection switch SSS. The two-state selection switch SSS selects and outputs one of the ground potential V_{SS} and a selection signal BS0 of the sub-array <0>. It is programmed in the fuse element 14 which of them the two-state selection switch SSS selects. The two-state selection switch SSS selects one of the ground potential V_{SS} and the selection signal BS0 on the basis of information programmed in the fuse element 14. The selection signal BS0 is a signal indicating whether the sub-array <0> is to be selected or not. The selection signal BS0 is obtained by decoding the row addresses RA4-RA9 by a sub-array decoder AD0. The selection signals WS0-WS15 are signals whether respective word lines WL0-WL15 are to be selected or not. The selections signals WS0-WS15 are obtained by decoding the row addresses RA0-RA3 by the word line decoders RS-0 to RS-15, respectively.

Further, an equalizing control driver ED-S supplies an AND of an equalizing signal EQB and an output of the two-state selection switch SSS to gates of equalizing drivers PM1 and PM2. The equalizing drivers PM1 and PM2 pre-charge the pair local bit lines BLS-0 and BLS-0B, respectively, to an equalizing potential, according to the output of the equalizing control driver ED-S. Further, a write control driver WD-S supplies an AND of a write enable signal WEB and an output of the two-state selection switch SSS to the gates of the write transfer gates NM1 and NM2. The write transfer gates NM1 and NM2 supply signals from the pair global bit lines GBL and GBLB to the pair local bit lines BLS-0 and BLS-0B, respectively, according to the output of the write control driver WD-S.

In the sub-array <0>, each of the word line drivers D0-0 to D0-15 outputs an AND of a selection signal (WS0-WS15) of its word line (WL0-WL15) and an output of a three-state selection switch SS0 to the word line (WL0-WL15). The three-state selection switch SS0 selects and outputs one of the ground potential V_{SS}, the selection signal BS0, and a selection signal BS1 of the sub-array <1>. It is programmed in the fuse element 14 which of them the three-state selection switch SS0 selects. The three-state selection switch SS0 selects one of the ground potential V_{SS} and the selection signals BS0 and BS1, based on the information programmed in the fuse element 14. The selection signal BS1 is a signal indicating whether the sub-array <1> is to be selected or not. The selection signal BS1 is obtained by decoding the row addresses RA4-RA9 by the sub-array decoder. The selection signals WS0-WS15 are signals whether respective word lines WL0-WL15 are to be selected or not. The selection signals WS0-WS15 are obtained by decoding the row addresses RA0-RA3 by the word line decoders R0-0 to R0-15, respectively.

Further, an equalizing control driver ED-0 supplies an AND of an equalizing signal EQB and an output of the three-state selection switch SS0 to gates of equalizing drivers PM3 and PM4. The equalizing drivers PM3 and PM4 pre-charge the pair local bit lines BL0-0 and BL0-0B, respectively, to an equalizing potential, according to the output of the equalizing control driver ED-0. Further, a write control driver WD-0 supplies an AND of a write enable signal WEB and an output of the three-state selection switch SS0 to the gates of the write transfer gates NM5 and NM6. The write transfer gates NM5 and NM6 supply signals from the pair global bit lines GBL and GBLB to the pair local bit lines BL0-0 and BL0-0B, respectively, according to the output of the write control driver WD-0.

A three-state selection switch SSn of a row decoder RD-n corresponding to a sub-array <n> (n=0, 1, . . . 63) selects and outputs one of the ground potential V_{SS}, and selection signals BSn and BSn+1. The row decoder RD-63 corresponding to the sub-array <63> has a two-state selection switch which selects one of the ground potential V_{SS} and a selection signal BS63 of the sub-array <63>, instead of a three-state selection switch.

In this embodiment, the correlations between the spare sub-array SA-S and the sub-arrays SA-0 to SA-63 and the sub-array decoders AD0-AD63 are changed by the program which determines selections in the two-state selection switches and the three-state selection switches. Thereby, it is possible to relieve a sub-array including a faulty memory cell by the spare sub-array, that is, to replace a sub-array including a faulty memory cell with the spare sub-array.

Next, a relief method of replacing a sub-array including a faulty memory cell with the spare sub-array is explained.

The two-state selection switch SSS and the three-state selection switch SS0 shown in FIG. 5 are in the state where none of the sub-arrays <0>-<63> have fault and fault relief is not performed. In this state, the two-state selection switch SSS selects the ground potential V_{SS}, and thus all the word lines WL0-WL15 of the spare sub-array SA-S are inactivated.

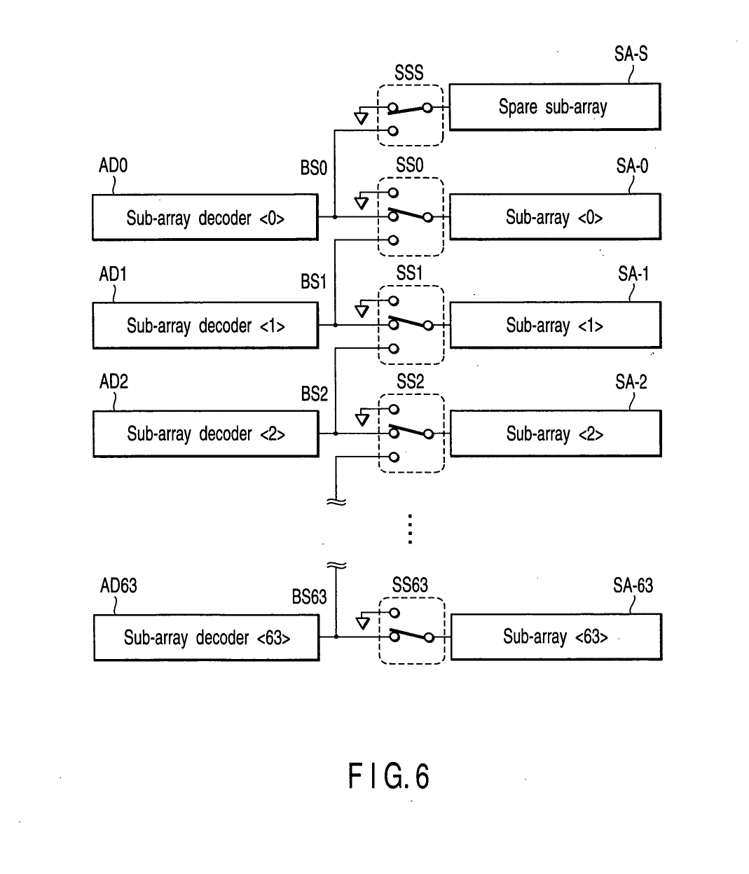

Further, in this state, the three-state selection switch SS0 selects the selection signal BS0, and thus the word lines of the sub-array <0> are activated or inactivated in response to the selection signal BS0 outputted from the sub-array decoder AD0. The state selection switches SS1 to SS63 (not shown) are programmed to select the selection signals BS1-BS63, respectively. Therefore, the sub-array <n> (n=1, 2, . . . , 63) is activated or inactivated in response to the selection signal BSn outputted from the sub-array decoder <n>. FIG. 6 schematically illustrates this state.

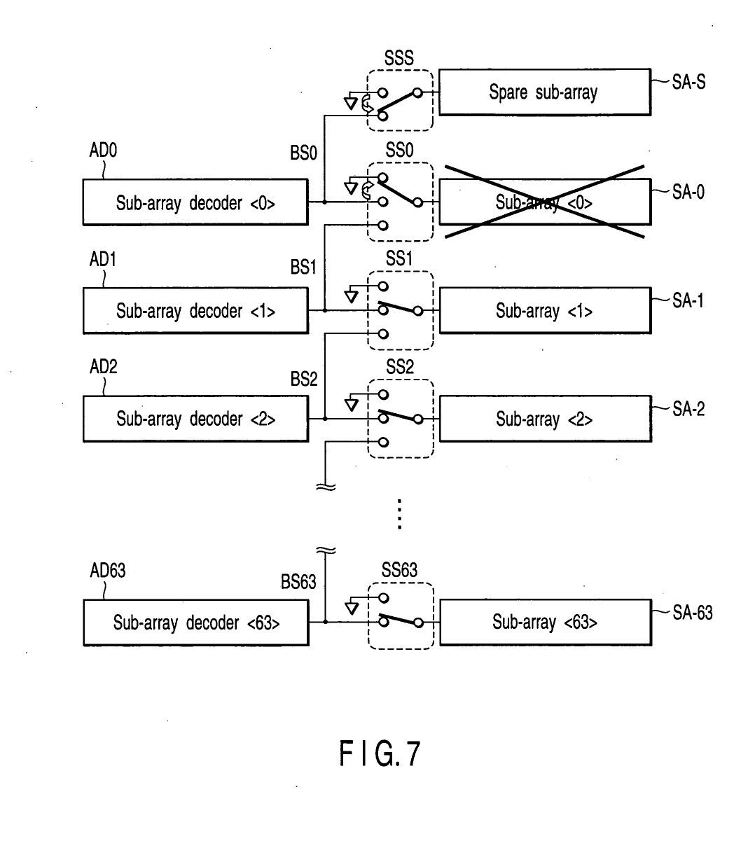

FIG. 7 is a schematic diagram illustrating the case where the sub-array <0> has fault and is replaced and relieved by the spare sub-array SA-S. In this case, it is programmed such that the two-state selection switch SSS selects the selection signal BS0 and the three-state selection switch SS0 selects the ground potential V_{SS}. Further, the state selection switches SS1 to SS63 are programmed to select the selection signals BS1 to BS63, respectively, in the same manner as shown in FIG. 6. Thereby, the sub-array <0> is inactivated, and the spare sub-array SA-S is activated in place of the sub-array <0>.

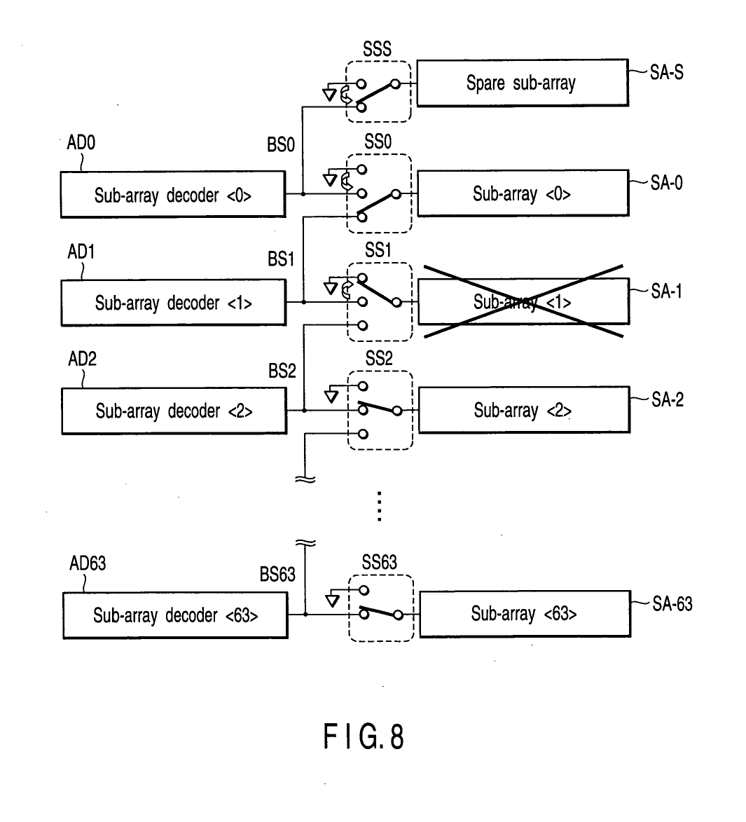

FIG. 8 is a schematic diagram illustrating the case where the sub-array <1> has fault and is replaced and relieved by the spare sub-array SA-S. It is programmed such that the two-state selection switch SSS selects the selection signal BS0, the three-state selection switch SS0 selects the selection signal BS1, and the three-state selection switch SS1 selects the ground potential V_{SS}. Further, the state selection switches SS2-SS63 are programmed to select the selection signals BS2-BS63, respectively. Generally, if a sub-array <n> has fault, the two-state selection switch SSS selects the selection signal BS0, the state selection switch SSi (i=0, 1, . . . , n−1) selects a selection signal Bsi+1, the state selection switch SSn selects the ground potential V_{SS}, and the state selection switches SSj (j=n+1, n+2, . . . , 63) is programmed to select the selection signal BSj.

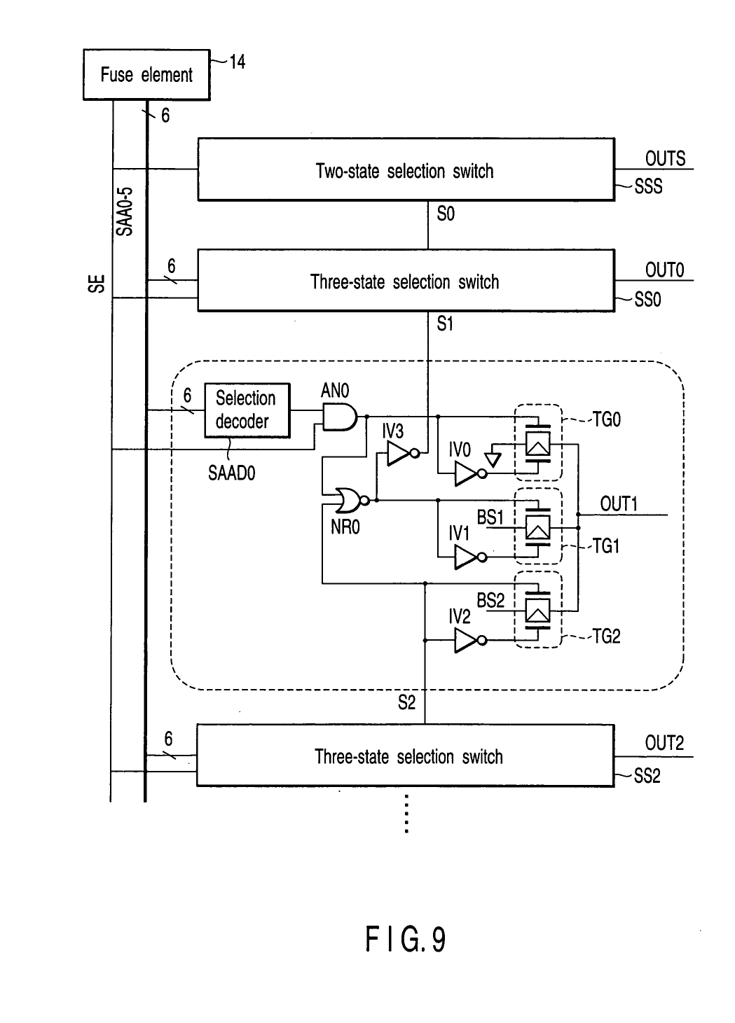

FIG. 9 is a circuit diagram illustrating a structure of three-state selection switch SS0-SS62. Although FIG. 9 illustrates only a structure of the three-state selection switch SS1, the structures of the other three-state selection switches are the same as that of the switch SS1.

The three-state selection switch SS1 comprises a selection decoder SAAD0, transfer gates TG0, TG1 and TG2, an AND circuit AN0, a NOR circuit NR0, and inverters IV0, IV1, IV2, IV3. A fuse element 14 is connected to the three-state selection switches SS0-SS62. Information of designating a sub-array including fault is inputted in the fuse element 14, and the fuse element 14 outputs a selection signal SAA0, SAA1, . . . , SAA5 (hereinafter referred to as “SAA0-5”) designating a sub-array including fault, and a relief enable signal SE which permits execution of fault relief. The selection decoder SAAD0 decodes the selection signal SAA0-5 outputted from the fuse element 14, and outputs a signal indicating whether the sub-array <1> corresponding to the three-state selection switch SS1 is selected or not (whether it is a sub-array including fault or not). The ground potential, a selection signal BS1 and a selection signal BS2 are supplied to the transfer gates TG0, TG1 and TG2, respectively, at respective one ends of current paths thereof. The transfer gates TG0, TG1 and TG2 are controlled to be turned on or off, and thereby one of the ground potential, selection signal BS1 and selection signal BS2 is outputted as the output signal OUT1.

The following is operation of the three-state selection switch SS1 shown in FIG. 9.

Information of designating a sub-array including fault is programmed in the fuse element 14. The fuse element 14 outputs 6 bits of selection signal SAA0-5 designating a sub-array including fault among the 64 sub-arrays <0>-<63>, and a relief enable signal SE which permits fault relief. When fault relief is performed, the relief enable signal SE is changed to “H”. The selection signal SAA0-5 and the relief enable signal SE are shared by the two-state selection switch SSS, the three-state selection switches SS0-SS62, and the two-state selection switch SS63.

For example, suppose that the sub-array <1> includes fault. In this case, the fuse element 14 outputs a selection signal SAA0-5 designating the sub-array <1>, and a signal “H” as the relief enable signal SE. The selection decoder SAAD0 decodes the selection signal SPA0-5, and outputs another signal “H” to a first input terminal of the AND circuit AN0. The signal “H” as the relief enable signal SE is inputted in a second input terminal of the AND circuit AN0, and a signal “H” is outputted from an output terminal of the AND circuit AN0 to the transfer gate TG0. Thereby, the transfer gate TG0 is turned on, and outputs the ground potential V_{SS} as the output signal OUT1. Specifically, when the three-state selection switch SS1 is designated by the selection signal SAA0-5, the three-state selection switch SS1 turns on the transfer gate TG0, and outputs the ground potential V_{SS} as the output signal OUT1. In this case, the signal S1 outputted from the inverter IV3 is set to “H”, and the three-state selection switch SS0 selects and outputs the selection signal BS1.

As shown in FIG. 9, generally, when the state selection switch SSn is selected and the relief enable signal SE is set to “H”, all the signals S0 to Sn are set to “H”. Thereby, the three-state selection switches SSi (i=0, 1, . . . , n−1) output a selection signal Bsi+1. Further, in this case, the state selection switch SSj (j=n+1, n+2, . . . , 63) outputs a selection signal BSj.

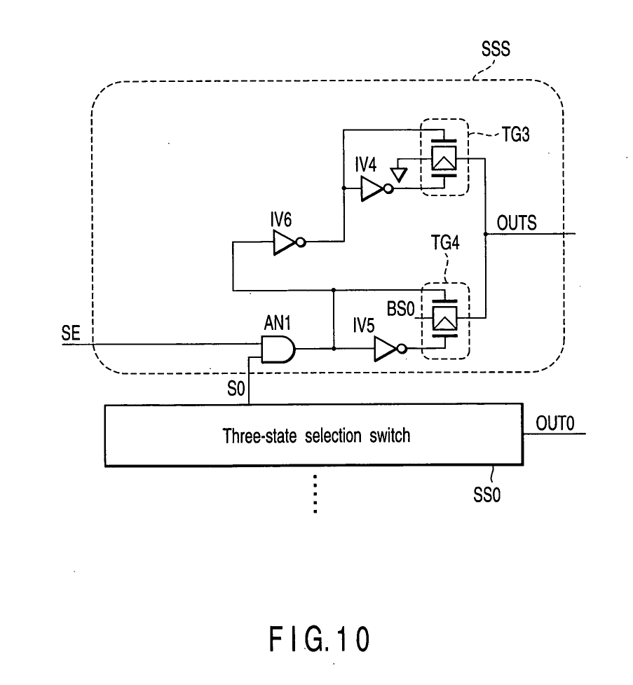

FIG. 10 is a circuit diagram illustrating a structure of the two-state selection switch SSS. The two-state selection switch SSS comprises transfer gates TG3 and TG4, an AND circuit AN1, and inverters IV4, IV5 and IV6. A relief enable signal SE from the fuse element 14 is input in the two-state selection switch SSS. A ground potential and a selection signal BS0 are supplied to the transfer gates TG3 and TG4, respectively, at respective one ends of current paths thereof. The transfer gates TG3 and TG4 are controlled to be turned on or off, and thereby one of the ground potential and the selection signal BS0 is outputted as the output signal OUTS.

The following is operation of the two-state selection switch SSS shown in FIG. 10.

As described above, when one of the sub-arrays <0>-<63> corresponding to the state selection switches SS0-SS63 is designated by the selection signal SAA0-5 and the relief enable signal SE is set to “H”, the signal S0 is set to “H”. Thereby, the transfer gate TG4 is turned on, and the selection signal BS0 is outputted as the output signal OUTS.

In the meantime, if there is no sub-array including fault and relief is unnecessary, the relief enable signal SE is set to “L”. Thereby, the transfer gate TG4 is turned off, the transfer gate TG3 is turned on, and the ground potential V_{SS} is outputted as the output signal OUTS.

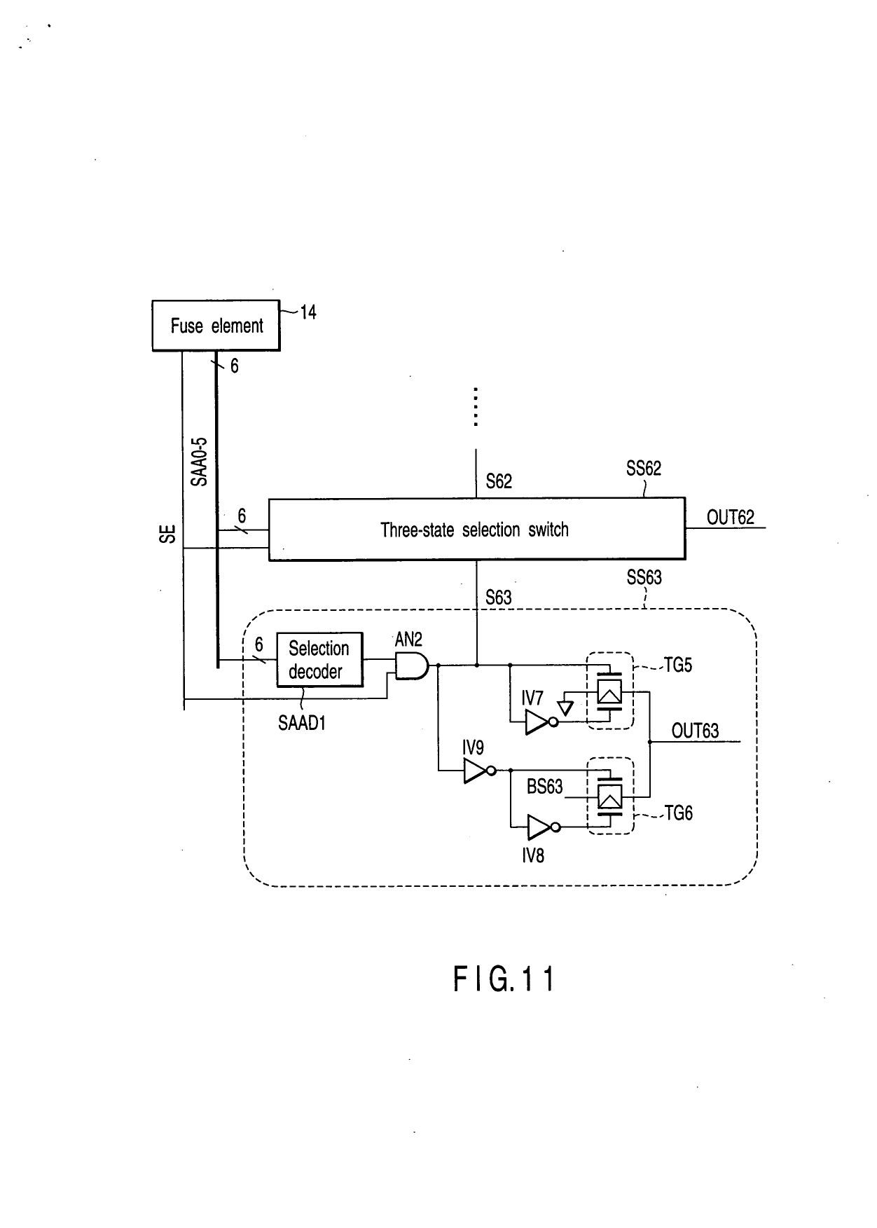

FIG. 11 is a circuit diagram illustrating a structure of the two-state selection switch SS63. The two-state selection switch SS63 comprises a selection decoder SAAD1, transfer gates TG5 and TG6, an AND circuit AN2, and inverters IV7, IV8 and IV9. The selection signal SAA0-5 designating a sub-array including fault and the relief enable signal SE are inputted from the fuse element 14 in the two-state selection switch SS63. The selection decoder SAAD1 decodes the selection signal SAA0-5 outputted from the fuse element, and outputs a signal indicating whether the sub-array <63> corresponding to the two-state selection switch SS63 is designated or not. The ground potential and the selection signal BS63 are supplied to the transfer gates TG5 and TG6, respectively, at respective one ends of current paths thereof. The transfer gates TG5 and TG6 are turned on or off, and thereby one of the ground potential and the selection signal BS63 is outputted as an output signal OUT63.

The following is operation of the two-state selection switch SS63 shown in FIG. 11.

When the sub-array <63> is designated by the selection signal SAA0-5 and the relief enable signal SE is set to “H”, a signal “H” is outputted from the AND circuit AN2. Thereby, the transfer gate TG5 is turned on, and the ground potential V_{SS} is outputted as the output signal OUT63.

In the meantime, when the sub-array <63> is not designated by the selection signal SAA0-5, the output of the selection decoder SAAD1 is “L”, and a signal “L” is outputted from the AND circuit AN2. Further, if there is no sub-array including fault and relief is unnecessary, the relief enable signal SE is set to “L”, and the signal “L” is outputted from the AND circuit AN2. In these cases, the transfer gate TG5 is turned off, the transfer gate TG6 is turned on and the selection signal BS63 is outputted as the output signal OUT63.

As described above, only when the relief enable signal SE is “H” and the two-state selection switch SS63 is designated by the selection signal SAA0-5, the ground potential V_{SS} is outputted as the output signal OUT63. In the other cases, the selection signal BS63 is outputted. By using the state selection switches shown in FIGS. 9-11, it is possible to configure an SRAM having state selection switches explained with reference to FIGS. 6-8.

In the embodiment having the above structure, a cell array has a spare sub-array and sub-arrays, and the spare sub-array and each of the sub-arrays has 16 word lines WL0-WL15. Each sub-array is not provided with a spare word line, unlike the conventional art. Specifically, in this embodiment, each sub-array does not have a spare word line, and instead one spare sub-array is provided for 64 sub-arrays. Then, a faulty row is relieved by replacing a sub-array including a faulty memory cell with the spare sub-array. This reduces the area of each sub-array, and allows reduction in the area of a memory cell array portion comprising a plurality of sub-arrays. In the above embodiment, the cell array area penalty of adding a spare sub-array is about 1.6 ( 1/64) %, and thus the embodiment has an advantage of reducing the penalty in comparison with the area penalty (about 6 ( 1/16) %) of the conventional art.

Further, when relieving a faulty memory cell, the embodiment does not need a faulty address detecting circuit for detecting input of an address designating a faulty memory cell, and thus achieves high-speed reading.

Further, when a threshold voltage of a transistor decreases with scale down of memory cells, leakage current from memory cells to bit lines increases in the case where the word line is not selected. In particular, the leakage current is conspicuous when memory cells are manufactured by the design rule of 65 nm or less. However, using a hierarchical bit line structure reduces the number of transistors connected to local bit lines, and reduces the noise caused by the leakage current. In this embodiment, the memory cells are formed by the design rule of 65 nm or less, and thereby it is possible to obtain the effect by using the above hierarchical bit line structure, that is, the effect of reducing the number of transistors and reducing noise due to the leakage current.

According to the embodiment of the present invention, it is possible to provide a semiconductor memory device which can reduce the area of a memory cell array portion, and reduce the chip area including the memory cell array portion.

The above embodiment is not the only embodiment, but various embodiments can be made by changing the structure or adding various structures. In the embodiment, although each of the spare sub-array and the sub-arrays has 16 word lines, each of them may have word lines of other numbers, for example, 8 or 32. Further, although the above embodiment shows an example in which one spare sub-array is provided for 64 sub-arrays, one spare sub-array may be provided for sub-arrays of other numbers, for example, 32 or 128 sub-arrays. Furthermore, although the above embodiment shows an example of applying the present invention to an SRAM, the present invention is not limited to SRAMs, but can be applied to semiconductor memory devices such as DRAM and EPR0M.

Additional advantages and modifications will readily occur to those skilled in the art. Therefore, the invention in its broader aspects is not limited to the specific details and representative embodiments shown and described herein. Accordingly, various modifications may be made without departing from the spirit or scope of the general inventive concept as defined by the appended claims and their equivalents.

1. A semiconductor memory device comprising:
a plurality of sub-arrays, in each of which memory cells are arranged in row and columns;
a spare sub-array which replaces a sub-array including a faulty memory cell in the plurality of sub-arrays, the spare sub-array including memory cells arranged in rows and columns;
a plurality of first local bit lines connected to the memory cells of the respective sub-arrays;
a second local bit line connected to the memory cells of the spare sub-array;
a global bit line shared by the plurality of first local bit lines and the second local bit line;
a plurality of transfer gates which set connections of each of the plurality of the first bit lines and the second local bit line to the global bit line to a connected state or a disconnected state;
a plurality of sub-array decoders which select the sub-arrays, the sub-array decoders being provided in correspondence with the respective sub-arrays;
a switch circuit which changes correlation between the sub-arrays and the spare sub-array and the sub-array decoders; and
a fuse element, in which the correlation in the switch circuit is stored, the fuse element outputting a signal indicating the correlation to the switch circuit.

2. A semiconductor memory device according to claim 1, wherein
if the sub-array including the faulty memory cell is relieved, the switch circuit correlates the spare sub-array and the sub-arrays not including fault with the sub-array decoders in a one-to-one relationship.

3. A semiconductor memory device according to claim 1, wherein
if the sub-array is not relieved, the switch circuit correlates the sub-arrays excluding the spare sub-array with the sub-array decoders in a one-to-one. relationship.

4. A semiconductor memory device according to claim 1, further comprising:
a buffer circuit which amplifies readout data read on the first local bit lines, and outputs the data to the global bit line.

5. A semiconductor memory device according to claim 4, wherein
each of the first local bit lines and the global bit line comprises a complementary data line pair, and the buffer circuit outputs the data read on one line of the complementary data line pair of the first local bit lines to one line of the complementary data line pair of the global bit line.

6. A semiconductor memory device according to claim 1, wherein
the memory cells include memory cells of an SRAM (static random access memory) type.

7. A semiconductor memory device comprising:
sub-arrays i (i=0, 1, . . . , N−1) of a number N (N is a natural number of 2 or more), in each of which memory cells are arranged in rows and columns;
a spare sub-array which replaces a sub-array including a faulty memory cell in the sub-arrays of the number N, the spare sub-array including memory cells arranged in rows and columns;
a plurality of first local bit lines connected to the memory cells of the respective sub-arrays;
a second local bit line connected to the memory cells of the spare sub-array;
a global bit line shared by the plurality of first local bit lines and the second local bit line;
a plurality of transfer gates which set connections of each of the plurality of the first bit lines and the second local bit line to the global bit line to a connected state or a disconnected state;
a plurality of sub-array decoders i (i=0, 1, . . . , N−1) of the number N which select the sub-arrays i of the number N , the sub-array decoders i of the number N being provided in correspondence with the respective sub-arrays i of the number N;
switch circuits of a number (N+1) which change correlation between the sub-arrays of the number N and the spare sub-array and the sub-array decoders of the number N; and
a fuse element, in which the correlation in the switch circuits of the number (N+1) is stored, the fuse element outputting a signal indicating the correlation to the switch circuits of the number (N+1).

8. A semiconductor memory device according to claim 7, wherein
if the sub-array including the faulty memory cell is relieved, the switch circuits correlate the spare sub-array and the sub-arrays of a number (N−1) not including fault with the sub-array decoders of the number N in a one-to-one relationship.

9. A semiconductor memory device according to claim 7, wherein
if the sub-array is not relieved, the switch circuits correlate the sub-array decoders i (i=0, 1, . . . , N−1) to the sub-arrays i (i=0, 1, . . . , N−1), and if a sub-array M in the sub-arrays is relieved, the switch circuits correlate a sub-array decoder 0 with the spare sub-array, a sub-array decoder j (j=1, 2, . . . , M) with a sub-array (j-1), and a sub-array decoder k (k=M+1, M+2, . . . , N) with a sub-array k.

10. A semiconductor memory device according to claim 9, wherein
the switch circuits of the number (N+1) are arranged in correspondence with the spare sub-array and the sub-arrays of the number N,
if the sub-array M is relieved, a switch circuit M corresponding to the sub-array M is selected by the signal outputted from the fuse element, and
by selection of the switch circuit M, the switch circuit 0 correlates the sub-array decoder 0 with the spare sub-array, a switch circuit 1 (1=1, 2, . . . , M−1) correlates the sub-array decoder j (j=1, 2, . . . , M) with the sub-array (j-1), and a switch circuit k (k=M+1, M+2, . . . , N) correlates the sub-array decoder k (k=M+1, M+2, . . . , N) with the sub-array k.

11. A semiconductor memory device according to claim 7, further comprising:
a buffer circuit which amplifies readout data read on the first local bit lines, and outputs the data to the global bit line.

12. A semiconductor memory device according to claim 11, wherein
each of the first local bit lines and the global bit line comprises a complementary data line pair, and the buffer circuit outputs the data read on one line of the complementary data line pair of the first local bit lines to one line of the complementary data line pair of the global bit line.

13. A semiconductor memory device according to claim 7, wherein the switch circuits of the number (N+1) are arranged in correspondence with the spare sub-array and the respective sub-arrays of the number N, a switch circuit corresponding to the spare sub-array selects one of an output of a sub-array decoder 0 and a signal which inactivates the spare sub-array, a switch circuit i (i=0, 1, . . . , N−2) selects one of an output of a sub-array decoder i, an output of a sub-array decoder (i+1), and a signal which inactivates the sub-array i, and a switch circuit (N−1) selects one of an output of a sub-array decoder (N−1) and a signal which inactivates a sub-array (N−1).

14. A semiconductor memory device according to claim 7, wherein the memory cells include memory cells of an SRAM (static random access memory) type.

15. A semiconductor memory device according to claim 14, wherein the memory cells are formed by a design rule of 65 nm or less.
